(19) United States
(12) Patent Application Publication
(10) Pub. No.: US 2007/0194919 A1
(43) Pub. Date: Aug. 23, 2007

(54) Method and device for localizing anomalies located inside an immersed hollow structure

(75) Inventors: Thierry Blanche, Suresnes (FR); Jean-Yves Satre, Chevreuse (FR); Robert Charles, Anthony (FR)

Correspondence Address: BROWDY AND NEIMARK, P.L.L.C.;624 NINTH STREET, NW, SUITE 300, WASHINGTON, DC, 20001-5303, US

(73) Assignee: Enertag, Suresness Cedex (FR)

(21) Appl. No.: 10/594,440

(22) PCT Filed: Dec. 13, 2004
(86) PCT No.: PCT/FR04/03211

§ 371 Date: Sep. 26, 2006

(30) Foreign Application Priority Data
Mar. 26, 2004 (FR) 0403250

(51) Int. Cl. G01R 31/08; G08B 13/14

(52) U.S. Cl. 340/572.1; 324/512

(57) ABSTRACT

A method for externally locating anomalies located inside an immersed hollow structure (PL), wherein said anomalies are previously detected by a device (RTE) moving inside said immersed hollow structure, and are positioned by counting a series of reference marks from an origin, said reference marks being located at regular intervals and being accessible from the inside and outside of said immersed hollow structure. The inventive method consists in defining by means of counting a reference mark, starting from said origin, which is accessible from the outside of the immersed hollow structure; positioning a transponder module (T) on said reference mark; identifying the transponder module (T) by an I.D. code; determining the number of reference marks separating the anomalies and the identified transponder module (T).

The present invention relates to a method and a device for localizing anomalies located inside an immersed hollow structure.

This method is notably but not exclusively applied to the maintenance of rigid or flexible submarine pipelines for transporting oils or gases between the production sites and the storage or distribution sites, and to the identification of submarine cables.

Generally speaking, it is known that a submarine pipeline consists of metal envelope, made from sections of steel tube and of an external protection made in concrete.

The sections have a length close to 12 meters and an external diameter generally between 12 inches and 36 inches; they are connected together by welding.

The concrete coat providing protection of the metal envelope has a thickness of about 2 to 5 centimeters.

Welding of the metal sections and coating the envelope with concrete are performed on the pipeline laying ship; which lays the pipeline continuously on the bottom of the marine environment according to a path defined beforehand and controlled by an absolute value positioning system.

Moreover, the pipelines may be laid in a non-rectilinear way, for reasons related to the nature of the ground; the sea beds are not necessarily horizontal; other pipelines may be present and form obstacles to be bypassed or overridden.

The identification of each of the submarine pipelines or submarine cables, indispensable for ensuring their maintenance, is carried out via passive elements, such as numbered plates or of different colors or via active elements such as acoustic beacons electrically powered by battery.

The passive devices are generally rapidly covered with concretions which make their reading difficult, or even impossible; the active devices have limited effectiveness considering the lifetime of the batteries.

Moreover it is known that maintenance of submarine pipelines is preceded by a visual and sometimes radiographic examination of the metal envelope via a robot moving inside the pipeline. The latter may thus detect anomalies, such as corrosion of the metal of the envelope, degradation of a weld connecting two sections, deformation of the metal envelope caused by an accidental displacement of the pipeline. This information may be stored in the robot itself, or transmitted in real time, to a control station, via an umbilical cord.

Localization of possible anomalies is carried out via welds between sections, thereby forming by counting from an origin, the reference system associated with the relevant pipeline.

Thus, localization of a reported anomaly by the observation robot at weld N, or of an anomaly reported between weld N and weld N+1, may be performed externally, in a second phase by identical counting of the welds, from the same origin, as the latter are indirectly apparent because of the nature of the concrete coating performed at said welds.

These internal control operations of submarine pipelines are costly, considering the means which are applied and moreover generate costs for immobilization of said means as well as operative losses related to temporary stopping of production.

Localization of possible anomalies should therefore be accurate and without any risks of error.

The identification means mentioned earlier only partially meet the sought-after goals.

More particularly, the object of the invention is therefore to suppress these drawbacks.

It proposes the carrying out of an external localization of anomalies located in an immersed hollow structure, which anomalies were detected beforehand by a device moving inside said immersed hollow structure and positioned by counting from an origin, marks located at regular intervals accessible inside and outside said immersed hollow structure, consisting of:
defining by counting, from the same aforesaid origin, a mark accessible outside the immersed hollow structure,
positioning a transponder module on the aforesaid mark,
identifying the transponder module by an identification code,
determining the number of marks which separate said anomalies and said identified transponder module.

Thus, counting from an origin generally defined as being the aperture for access to the pipeline, of the number of marks such as the welds connecting the different sections together, which are directly visible inside the metal envelope and indirectly outside the pipeline, forms a reference system associated with the relevant pipeline.

Of course, this reference system relative to the pipeline is not an absolute value positioning reference system of said pipeline. Other means may be applied with which the topographic relationship may be defined between this relative reference system of the pipeline and the absolute value positioning system accessible at the surface.

In a more specific way, the identification of the reference system relative to the pipeline formed by marks accessible inside and outside as are in this case the welds connecting the sections, is performed via transponders which comprise an identification code.

Thus, near all the n welds (n being equal to or larger than 1), transponders will be mechanically integral with the pipeline, each of said transponders including at least one identification code specific to the pipeline and to the weld associated with the corresponding transponder.

A low power device for remote reading of the transponder comprising receiving means coupled with a receiving antenna for remotely sensing the signal emitted by the transponder when it is placed near the latter, and means for processing the received signal and for providing corresponding information to the received signal, will enable the weld associated with said transponder to be identified without any risks of error.

By these arrangements, the counting of the welds performed during the internal observation phase of the pipeline allowing localization of a possible anomaly, associated with the external identification of the welds, performed by reading the identification code of the corresponding transponder, will allow said anomaly observed inside to be localized from the outside.

According to a particularity of the invention, the reading device may comprise means for storing information corresponding to the received signal and means for remotely transmitting the identification code read to a receiving station comprising a computer terminal.

According to another particularity of the invention, the reading device may comprise means for writing information into a writing and reading memory of the transponder, for example concerning the characteristics of the maintenance operation, the operational conditions under which the maintenance operations are performed.

Reading and writing information into the writing and reading memory of the transponder may be performed in situ, in an immersed environment, but also beforehand at the surface before immersion of said transponder; in this case, data defining the initial conditions specific to the relevant immersed structure, are written into the memory of the transponder, notably prior to its immersion.

Advantageously, the operating frequencies for reading and writing information into the reading and writing memory of the transponder will be those which are today standardized for free propagation in air, i.e., 125 kHz and 134 kHz; taking into account that for the moment there is no standardization in the marine environment, the operating frequencies preferentially will be lower in order to promote propagation of the magnetic component of the electromagnetic field generated by the reading and writing device; the operating frequencies may be between 1 kHz and 50 kHz.

As for the powers generated by the reading and writing device, there are between 1 W and 100 W, preferably between 4 W and 20 W.

As an example, the operating characteristics may be the following:

Frequency: 125 kHz; power: 4 W; reading and writing distance separating the reading and writing device from the transponder: 50 cm.

Advantageously, the methods for permanent integration of the transponder in situ into the immersed hollow structure may be bonding, the use of straps, or the use of open collars; during assembly at the factory, the methods for permanent integration will essentially be of the kind with a peg fixed or embedded in the coating of the hollow structure, made in concrete or in resin.

An embodiment of the method according to the invention will be described hereafter, as a non-limiting example, with reference to the appended drawings wherein:

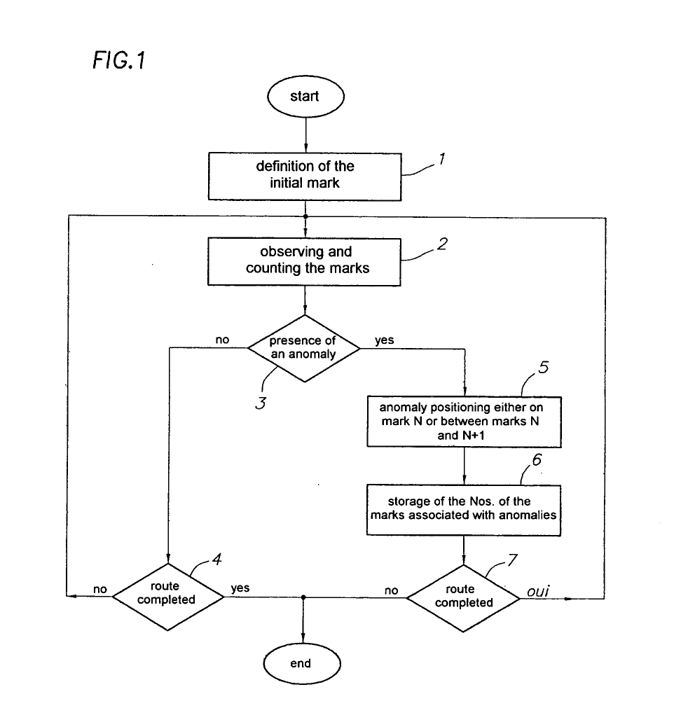

FIG. 1 illustrates a flowchart for localizing anomalies inside an immersed hollow structure,

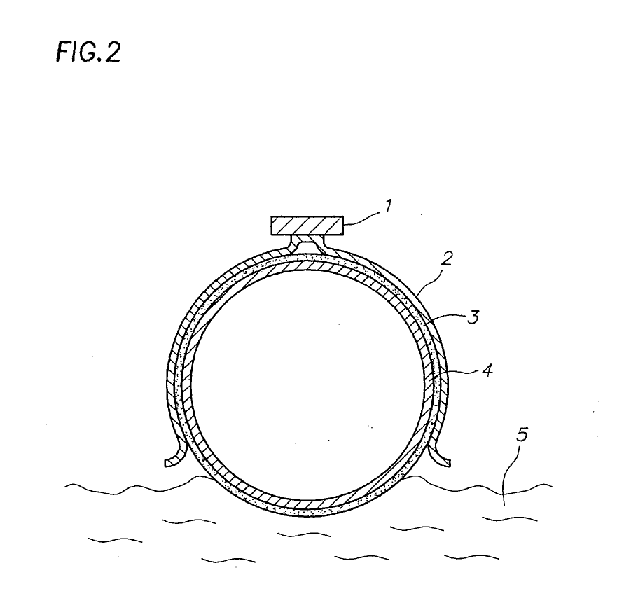

FIG. 2 illustrates a schematic view of a first means for permanently integrating the transponder,

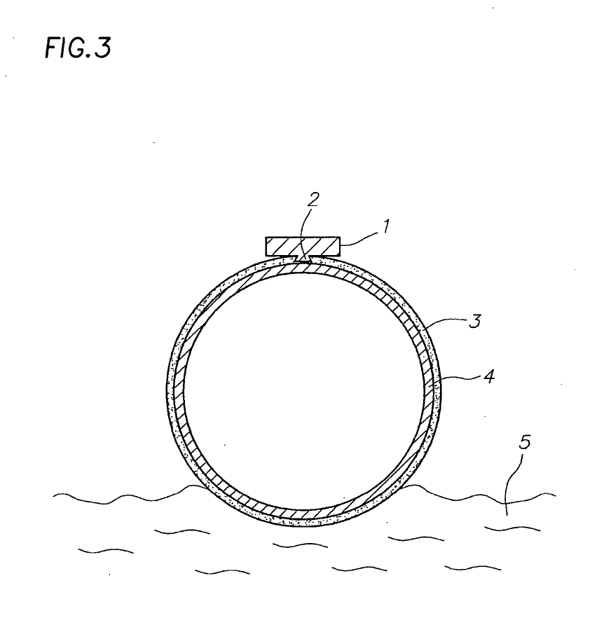

FIG. 3 illustrates a schematic view of a second means for permanently integrating the transponder,

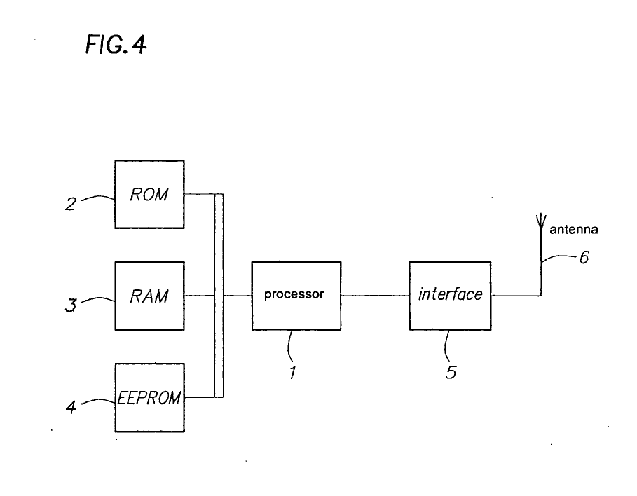

FIG. 4 illustrates a block diagram of an exemplary architecture of a transponder,

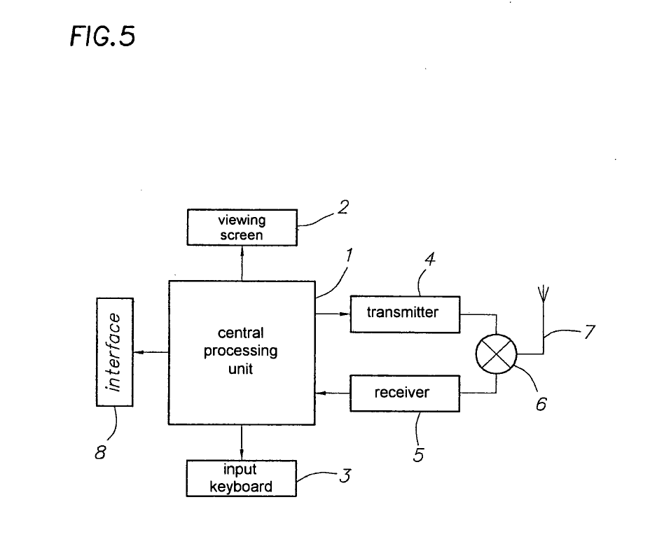

FIG. 5 illustrates a block diagram of an exemplary architecture of a reading and writing device,

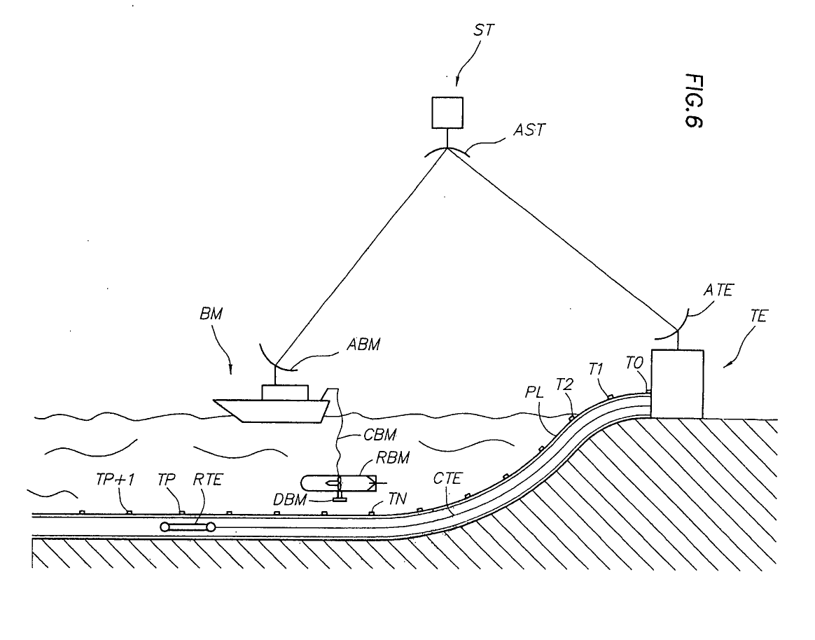

FIG. 6 illustrates a simplified diagram of a system for inspecting a submarine pipeline.

In the example illustrated in FIG. 1, the method for localizing anomalies located inside an immersed hollow structure comprises the following steps:

defining the original mark (block 1), so that the same origin may be assigned for the phases for internal observation of the structure and for external localization of a possible anomaly in said structure,

internally observing the structure and counting the marks (block 2),

test for the presence of an anomaly (block 3):
no anomaly: test on whether the route was covered (block 4); if yes, end of the localization method; if no, continue with the method and return (block 2),
presence of an anomaly: next step.

positioning the observed anomaly (block 5):
either in the vicinity of a mark N,
either between marks N and N+1,

storing marks associated with the observed anomalies (block 6),

test whether the route was covered (block 7): if yes, end of the localization method; if no, continue with the method and return (block 2).

As defined earlier, said marks accessible from the inside and from the outside are in this case welds connecting the sections of the submarine pipeline. Moreover, near the n welds (n being equal to or larger than 1), transponders are mechanically integral with the external envelope of the pipeline.

This envelope made in concrete, provides protection of the metal sections; two cases may occur:
the pipeline is immersed and the permanent integration of the transponder must be performed in situ,
the pipeline is being laid and the permanent integration of the transponder may be performed during the concrete layer coating operation.

In the example illustrated in FIG. 2, the pipeline illustrated in a sectional view, consists of a metal envelope 4, covered with a concrete coating 3; the whole rests on the sea bed 5.

Localization of the transponder should, consequently, be carried out in situ.

The transponder 1 is integral with an open collar 2, made in a flexible material, unaffected by seawater; which collar because of its elasticity, enables the transponder 1 to be positioned in the vicinity of the weld connecting two sections forming the metal envelope 4.

Moreover, the transponder 1 will be positioned in the vicinity of the upper generatrix of the pipeline, in order to facilitate the reading of the identification code of the transponder and consequently of the corresponding weld.

In the example illustrated in FIG. 3, the pipeline illustrated as a sectional view consists of a metal envelope 4, covered with a concrete coating 3; the whole rests on the seabed 5; nevertheless completion of the concrete coating was carried out beforehand on board the pipeline laying ship.

In this case, the transponder 1 will comprise a sealing member 2 so as to permanently integrate the transponder into the pipeline during the setting of the coating concrete.

In the example illustrated in FIG. 4, the architecture of a transponder essentially comprises:
a processor 1, for managing the peripherals, i.e.:
a ROM memory 2, for containing the instructions of the operating system,
a RAM memory 3, for temporarily storing the data during the reading and writing operations,
an EEPROM type memory 4, for writing and reading identification data,
a HF transceiver interface 5,
an antenna 6.

The transponders used according to the invention, may preferably be of the passive type; indeed, the active transponders are powered with an electric power source, and consequently have a limited lifetime.

In the case of passive transponders, the electromagnetic energy emitted by the reading and writing device induces at the antenna of the transponder, electrical power able to power the different devices of the transponder.

The operating frequencies of the authorized transponders are the following: 125 kHz, 13.56 MHz, 2.45 GHz as well as the 860-926 MHz band and 433 MHz.

In the present case, taking into account the immersion of the transponder in an aquatic environment, the carrier frequency will be 125 kHz; the emitting power of the reading and writing device will be close to 4 W; with these characteristics, the transponder may thereby be read at a distance close to 50 cm, and data may be written into the memory of the transponder when close to the latter.

In the example illustrated in FIG. 5, the architecture of a reading and writing device essentially comprises:
a central processing unit 1,
a viewing screen 2,
a writing keyboard 3,
a HF power transmitter 4,
a large gain HF receiver 5,
a duplexer 6,
an antenna 7,
an external link interface 8.

These different elements are powered by a standalone electric battery or by an external electric power source, through an umbilical cord, which power source may be located on board a maintenance surface ship or on board a submarine robot carrying out the inspection of the immersed structures.

Thus, it may be considered that elements 4, 5, 6, 7 form the transmitter portion and elements 1, 2, 3, 8 form the reading/writing portion.

With the interface 8, it is possible to communicate with a management centre responsible for conducting the maintenance operations.

In the example illustrated in FIG. 6, the different actors responsible for maintenance of submarine pipelines are illustrated.

The scale of certain actors is not observed with the purpose of facilitating the description of the schematic structure of an inspection system of a submarine pipeline.

A pipeline PL rests on the seabed and is immersed near a terminal TE; with the latter, it is notably possible to access the inside of the pipeline in order to carry out maintenance.

In the present case, a robot R_{TE} for observation and possibly radiography, e.g. of the “ROV” (remotely operated vehicle) type, follows the inside of the pipeline while being connected via an umbilical cord C_{TE} to the inspection and control station of the robot R_{TE} located in the terminal TE; the umbilical cord C_{TE} notably comprises electric power supply circuits, the remote control link, as well as the video link associated with an on-board camera.

A plurality of transponders T₀, T₁, T₂ . . . T_{N} . . . T_{P}, T_{P+1} . . . are positioned on the envelope of the pipeline PL, near the corresponding welds connecting the metal sections.

A maintenance ship BM navigating above the pipeline controls the course of a submarine robot R_{BM}, via an umbilical cord C_{BM}; the robot R_{BM} notably comprises an observation camera with which the pipeline and a reading and writing device D_{BM} may be viewed.

A radiofrequency link connects the maintenance ship BM and the terminal TE via a telecommunications satellite ST and their respective antennas A_{BM}, A_{TE}, A_{ST}.

Thus, by deploying these means, it becomes possible to intervene in real time on a submarine pipeline following the detection of an anomaly observed inside the pipeline.

The whole of the collected information will be stored on board the management centre of the maintenance ship BM.

Moreover, the submarine robot R_{BM} may write into the different transponders information consecutive to the maintenance operation, i.e.:

the Customer reference,

the geographical reference: longitude, latitude, depth,

the pipeline reference: laying date, weld no., . . .

the intervention reference: name of the diver, date, . . . and transmit to the management centre, the intervention data (date, time, intervening operator, references of the read transponders, . . . ), intervention conditions (temperature, salinity, pH, . . . ), and other relevant data.

Thus, the method according to the invention for localizing anomalies located inside an immersed hollow structure, allows the maintenance operations to be carried out in order to meet the sought-after goals, i.e.:
a quasi-zero risk of errors,
reduced intervention times and consequently reduced immobilization costs and operative losses.

Moreover, the utilization of transponders installed in situ, provides better knowledge on the maintenance conditions, and enrichment of the database guaranteeing better quality of the maintenance operations.

1. A method for external localization of anomalies located in an immersed hollow structure, which anomalies were detected beforehand by a device moving inside said immersed hollow structure, and positioned by counting from an origin, marks located at regular intervals accessible from the inside and outside of said immersed hollow structure, consisting of:
a. defining by counting, from the same aforesaid origin, a mark accessible on the outside of the immersed hollow structure,
b. positioning a transponder module on the aforesaid mark,
c. identifying the transponder module by an identification code,
d. determining the number of marks separating said anomalies and said identified transponder module.

2. The method according to claim 1, wherein the immersed hollow structure is a submarine pipeline.

3. The method according to claim 1, wherein the marks located at regular intervals accessible inside and outside of said immersed hollow structure are welds connecting metal sections forming the envelope of the hollow structure.

4. The method according to claim 1, wherein a transponder is located near one aforesaid weld.

5. The method according to claim 1, wherein the identification of the transponder module by an identification code is carried out via a reading and writing device.

6. The method according to claim 5, wherein the identification of the transponder module by an identification code is carried out at a frequency between 1 kHz and 150 kHz, preferably at 125 kHz and 134.2 kHz and at a power between 1 W and 100 W, preferably between 4 W and 20 W.

7. The method according to claim 5, wherein the reading and writing device comprises storage means and remote transmission means.

8. A device for applying the method according to claim 1, for external localization of anomalies located in an immersed hollow structure, which anomalies were detected beforehand by a device moving inside said immersed hollow structure, and positioned by counting from an origin, marks located at regular intervals, accessible from the inside and outside of said immersed hollow structure, said device comprising:
a. means for defining by counting, from the same aforesaid origin, a mark accessible on the outside of the immersed hollow structure,
b. means for positioning a transponder module on the aforesaid mark,
c. means for identifying the transponder module by an identification code,
d. means for determining the number of marks separating said anomalies and said identified transponder module.

9. The device according to claim 8, wherein the means for positioning the transponder module on the aforesaid mark comprise an open collar made in a flexible material unaffected by seawater.

10. The device according to claim 8, wherein the means for positioning the transponder module on the aforesaid mark, comprise a strap made in a flexible material unaffected by seawater.

11. The device according to claim 8, wherein the means for positioning the transponder module on the aforesaid mark consist in a bond unaffected by seawater.

12. The device according to claim 8, wherein the means for positioning the transponder module on the aforesaid mark comprise a sealing member in the concrete or the coating resin of said immersed hollow structure.

13. The device according to claim 8, wherein the means for identifying the transponder module by an identification code comprise a reading and writing device.

14. The device according to claim 11, wherein the aforesaid reading and writing device may write initial data in the transponder module before immersion.

15. The device according to claim 8, wherein the immersed structure is a flexible or rigid submarine pipeline, or a submarine cable.
